(19) United States
(12) Patent Application Publication
(10) Pub. No.: US 2012/0319293 A1
(43) Pub. Date: Dec. 20, 2012

(54) MICROELECTRONIC DEVICE, STACKED DIE PACKAGE AND COMPUTING SYSTEM CONTAINING SAME, METHOD OF MANUFACTURING A MULTI-CHANNEL COMMUNICATION PATHWAY IN SAME, AND METHOD OF ENABLING ELECTRICAL COMMUNICATION BETWEEN COMPONENTS OF A STACKED-DIE PACKAGE

(76) Inventors: Bok Eng Cheah, Bayan Lepas (MY); Shanggar Periaman, Penang (MY); Kooi Chi Ooi, Glugor (MY)

(21) Appl. No.: 13/162,799

(22) Filed: Jun. 17, 2011

(51) Int. Cl. H01L 23/48; H01L 21/28

(52) U.S. Cl. 257/774; 438/667; 257/E23.011; 257/E21.158

(57) ABSTRACT

A microelectronic device comprises a first surface (110, 710), a second surface (120, 720), and a passageway (130, 730) extending from the first surface to the second surface. The passageway contains a plurality of electrically conductive channels (131, 132, 231, 232) separated from each other by an electrically insulating material (133, 1133).

### FIELD OF THE INVENTION

The disclosed embodiments of the invention relate generally to microelectronic devices and packages, and relate more particularly to vias for such devices and packages.

### BACKGROUND OF THE INVENTION

Consumer electronic devices, particularly smart phones, tablets, and others that are designed to be portable, have for many years been subject to a trend toward smaller and thinner form factors. This trend has been at odds with the increasing complexity and functionality of such devices, which, in the absence of improving manufacturing and packaging techniques, would require extensive platform or motherboard space in order to integrate CPUs, chipsets, memory, sensors, and/or various other functional devices using multiple packages. Form factor and space constraints have been addressed using various 3D and system-in-package design technologies, e.g., mixed-stacked packages using both flip-chip and wirebond solutions, 3D-stacked packages (possibly using vias extending through a lower die), Package-On-Package (POP) devices, and multi-chip packages (MCP).

Techniques like those mentioned above have been important stepping stones leading toward smaller device form factors, but they do face certain obstacles. For example, the input/output (I/O) density for devices on upper layers in mixed-stacked packages (i.e., packages using both flip-chip and wirebond solutions) is limited by wirebond pad counts. As another example, existing techniques for through silicon via (TSV) fabrication are both inefficient and costly, at least in part because each laser drilling step produces only a single TSV channel in present 3D-stacked packaging technology.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a microelectronic device according to an embodiment of the invention;

FIG. 2 is a plan view of a portion of the microelectronic device of FIG. 1 according to an embodiment of the invention;

FIG. 3 is a cross-sectional view of a stacked die package according to an embodiment of the invention;

FIG. 4 is a schematic representation of a computing system according to an embodiment of the invention;

FIG. 5 is a flowchart illustrating a method of manufacturing a multi-channel electrical communication pathway in a microelectronic device according to an embodiment of the invention;

FIG. 6 is a flowchart illustrating a method of enabling electrical communication between components of a stacked-die package according to an embodiment of the invention;

FIGS. 7-9 and 11 each include cross-sectional and plan views of a microelectronic device at various stages in its manufacturing process, according to embodiments of the invention; and

FIG. 10 is a plan view of a laser etch mask that may be used in connection with methods according to embodiments of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Certain figures may be shown in an idealized fashion in order to aid understanding, such as when structures are shown having straight lines, sharp angles, and/or parallel planes or the like that under real-world conditions would likely be significantly less symmetric and orderly. The same reference numerals in different figures denote the same elements, while similar reference numerals may, but do not necessarily, denote similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions unless otherwise indicated either specifically or by context. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic device comprises a first surface, a second surface, and a passageway extending from the first surface to the second surface. The passageway contains a plurality of electrically conductive channels separated from each other by an electrically insulating material. As further discussed below, such passageways will often be referred to herein as multi-channel (MC) through silicon vias, or MC-TSVs.

In many (if not most) cases the microelectronic device will be silicon based—that is, silicon will constitute a large portion of the device. In those cases the passageway mentioned above may properly be called a through silicon via, or TSV, and these terms (“passageway,” “through silicon via,” and “TSV”) will be used interchangeably herein. In this regard, it should be noted that “TSV” and “through silicon via” have, because of the ubiquitous use of silicon in the semiconductor industry, become conventional terminology for any passageway of the type described above, and that convention will be followed here in references to such passageways, whether or not they are formed in silicon.

Die to die direct interconnection in microelectronics applications is mainly limited by the number of channels per area. Embodiments of the invention enable multiple channels within a single TSV. Conventional TSV interconnections provide a 1:1 ratio of channel to TSV, whereas embodiments of the invention can provide channel: TSV ratios of 2:1, 3:1, 4:1 or more. (Higher ratios may depend to at least some degree on the improvement of laser technology.) Embodiments of the invention enable a compact integrated package system with high functionality—critical characteristics for next-generation digital applications (e.g., Mobile Internet Devices (MIDs), Personal Digital Assistants (PDAs), smart-phones, tablets, digital cameras, and the like). Laser drilling, for example, provides low cost as well as shorter through put time (TPT) per channel connection.

As mentioned above, embodiments of the invention involve TSVs that have multiple electrically conductive channels therein. In various embodiments such MC-TSVs significantly increase the interconnection density between dies, e.g., between an upper die and a lower die in a stacked package. Accordingly, the various embodiments provide increased I/O capability and increased electrical path options within stacked silicon devices and other multi-chip packages. Higher signal-to-ground ratio and shorter current return path, both resulting in better signal integrity performance, can also be achieved using embodiments of the invention.

Furthermore, embodiments of the invention enable the integration of multiple devices, thus allowing further miniaturization of overall microprocessor package and motherboard form factors. For example, CPUs, netcom/application/graphic processors, chipsets, memory, and so forth may, according to embodiments of the invention, be combined into a single compact package. Moreover, both communication speed and efficiency among functional devices may be improved by the direct communication and shorter interconnection paths made possible by the increased interconnection channel density exhibited by embodiments of the invention (e.g., CPU to chipset, CPU to memory, etc.)

In addition to enabling greater interconnection density, the MC-TSVs of embodiments of the invention may lead to cost savings because of efficiencies that arise out of certain manufacturing methods that may be used to create them. For example, since two or more conductive channels are formed in each passageway, the number of laser drilling steps (that are used to create the passageways) needed for a given number of conductive channels may be reduced by at least a factor of two as compared to existing methods.

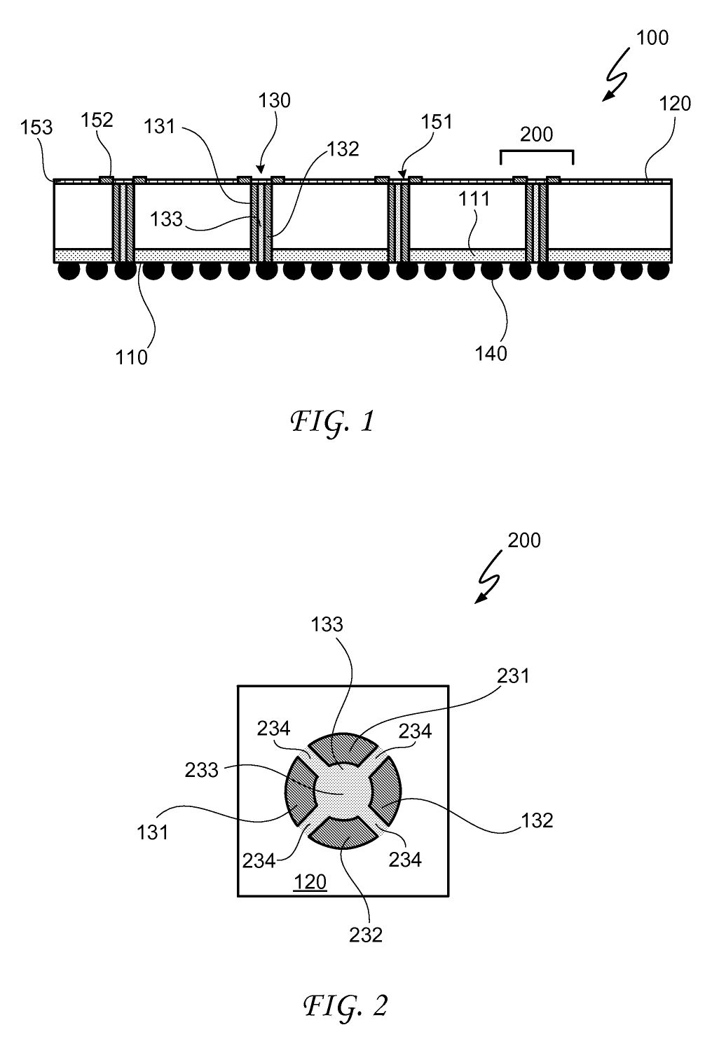

Referring now to the drawings, FIG. 1 is a cross-sectional view of a microelectronic device 100 according to an embodiment of the invention. As an example, microelectronic device 100 can be a semiconductor chip (or “die”) or some other type of integrated circuit (IC) device. In one embodiment, microelectronic device 100 includes a processing system (either single core or multi-core). For example, microelectronic device 100 may comprise a microprocessor, a graphics processor, a signal processor, a network processor, a chipset, etc. In one embodiment, microelectronic device 100 comprises a system-on-chip (SoC) having multiple functional units (e.g., one or more processing units, one or more graphics units, one or more communications units, one or more signal processing units, one or more security units, etc.). However, it should be understood that the disclosed embodiments are not limited to any particular type or class of IC device.

As illustrated in FIG. 1, microelectronic device 100 comprises a surface 110, a surface 120, and a passageway 130 extending from surface 110 to surface 120. Passageway 130 contains a plurality of electrically conductive channels, which can be symmetric or non-symmetric within passageway 130, separated from each other by an electrically insulating material. These are represented in FIG. 1 by electrically conductive channels 131 and 132 and an electrically insulating material 133. As an example, the electrically insulating material can comprise epoxy or dielectric material, and the electrically conductive material inside the electrically conductive channels can comprise a conductive metal (e.g., copper) or a micro-fiber, nano-fiber, or composite matrix material (e.g., organic, polymeric, ceramic, glass, metallic, or carbonaceous materials and/or any combinations thereof).

In the illustrated embodiment, surface 110 has an electrically conductive structure 140 attached thereto and surface 120 has an electrically conductive trace 151 formed thereon. As an example, electrically conductive structure 140 can be a C4 (controlled collapse chip connect) bump or the like and electrically conductive trace 151 can be a portion of a die backside metallization (DBM) layer or the like. The DBM layer also includes DBM pads 152 and a passivation layer 153. An active metal layer 111 is located near surface 110. (In some embodiments, surface 110 itself may be referred to as the “active surface” of microelectronic device 100.)

Electrically conductive structure (or “interconnect”) 140 may be part of an array or grid made up of many similar or identical structures. Interconnects 140 may comprise any type of structure and any type of material or combination of materials capable of providing electrical communication between microelectronic device 100 and other microelectronic components, e.g., other components of a microelectronic package. In the embodiment of FIG. 1, each of the interconnects 140 comprises an electrically conductive terminal on the microelectronic device (e.g., a pad, bump, stud bump, column, pillar, or other suitable structure or combination of structures), with the component to which it is to be joined having a corresponding electrically conductive terminal. Solder (e.g., in the form of balls or bumps) may be disposed on the terminals of the microelectronic device and/or other component, and these terminals may then be joined using a solder reflow process. Of course, it should be understood that many other types of interconnects and materials are possible (e.g., wirebonds extending between the components to be electrically connected.

The terminals on microelectronic device 100 (as well as those on the component to be joined thereto) may comprise any suitable material or combination of materials, whether disposed in multiple layers or combined to form one or more alloys and/or one or more intermetallic compounds. For example, the terminals may include copper, aluminum, gold, silver, nickel, titanium, tungsten, as well as any combination of these and/or other metals. Any suitable solder material may be used to join the mating terminals. For example, the solder material may comprise any one or more of tin, copper, silver, gold, lead, nickel, indium, as well as any combination of these and/or other metals. The solder may also include one or more additives and/or filler materials in order to alter a characteristic of the solder (e.g., to alter the reflow temperature).

In some embodiments, passageway 130 is cylindrical, meaning that it has a shape roughly resembling a cylinder, with a roughly circular cross section. An example is shown in FIG. 2, which is a plan view (looking down at surface 120) of a portion 200 of microelectronic device 100 according to an embodiment of the invention. Portion 200 is centered over one of passageways 130, and is indicated by a bracket in FIG. 1. For clarity, electrically conductive trace 151 and passivation layer 153 are omitted from FIG. 2. Referring still to FIG. 2, electrically insulating material 133 comprises a center portion 233 that is centrally located within the cylindrical passageway, and further comprises a plurality of arms 234 that radiate outward from center portion 233. Alternatively, the electrically insulating material could be arranged in some other (non-illustrated) configuration—such as a grid pattern, for example—that results in a plurality of electrically conductive channels that are electrically isolated from each other.

In FIG. 2, four electrically conductive channels are visible within passageway 130. These include electrically conductive channels 131 and 132, also visible in FIG. 1, and also include electrically conductive channels 231 and 232. This multi-channel TSV (passageway 130) with these four electrically conductive channels (131, 132, 231, 232) offers through-die electrical communication ability that is equivalent to four single-channel TSVs but in a space that is far more compact and at a much lesser cost. MC-TSVs with more than four (or with two or three) electrically conductive channels are also possible, and all such MC-TSVs offer these and other advantages, as described herein, over single-channel TSVs.

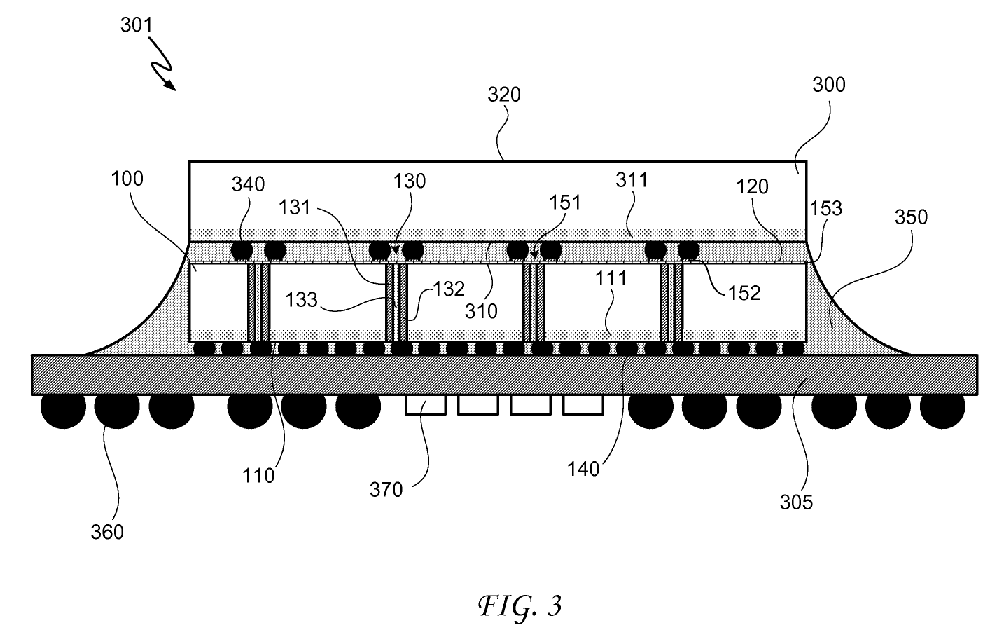

FIG. 3 is a cross-sectional view of a stacked die package 301 according to an embodiment of the invention. As illustrated in FIG. 3, stacked die package 301 comprises a substrate 305 to which two microelectronic devices are electrically connected. One of these is microelectronic device 100 that was introduced previously and that is shown in FIG. 1. The other is a microelectronic device 300 that is first shown in FIG. 3. Passageway 130 is a MC-TSV that enables high speed/high performance electrical communication between microelectronic device 300 and microelectronic device 100 and/or other components of stacked die package 301. (It should be noted here that die packages according to embodiments of the invention are not limited to two stacked dies; any appropriate number of dies or other microelectronic devices may be included in the stacked package, as desired.) Microelectronic device 300 comprises a surface 310, an opposing surface 320, and an active metal layer 311 near surface 310.

Substrate 305—sometimes referred to as a “package substrate”—may comprise any suitable type of substrate capable of providing electrical communications between microelectronic device 100 (or another device or component of package 301) and a next-level component to which package 301 is coupled (e.g., a circuit board). In another embodiment, substrate 305 may comprise any suitable type of substrate capable of providing electrical communication between microelectronic device 100 and an upper IC package coupled with package 301, and in a further embodiment the substrate 305 may comprise any suitable type of substrate capable of providing electrical communication between the upper IC package and a next-level component to which package 301 is coupled. The substrate 305 may also provide structural support for microelectronic device 100.

By way of example, in one embodiment substrate 305 comprises a multi-layer substrate—including alternating layers of a dielectric material and metal—built-up around a core layer (either a dielectric or metal core). In another embodiment, substrate 305 comprises a coreless multi-layer substrate. Other types of substrates and substrate materials may also find use with the disclosed embodiments (e.g., ceramics, sapphire, glass, etc.). Further, according to one embodiment, substrate 305 may comprise alternating layers of dielectric material and metal that are built-up over microelectronic device 100 itself. (This process is sometimes referred to as a bumpless build-up layer (BBUL) process.) Where such an approach is utilized, electrically conductive structure 140 may not be needed (because the build-up layers may be disposed directly over microelectronic device 100).

In the illustrated embodiment, stacked die package 301 further comprises an electrically conductive structure 340 attached to surface 310 of microelectronic device 300. As an example, electrically conductive structure 340 can be a die-to-die solder interconnect or the like. The illustrated embodiment of stacked die package 301 still further comprises an underfill material 350 adjacent to electrically conductive structure 340 (and also to electrically conductive structure 140), an electrically conductive structure 360 (these could be BGA balls (illustrated), LGA pads, PGA pins, or any other suitable type of electrically conductive structure), and additional devices 370 (e.g., such as the illustrated land-side capacitors (LSCs)). Underfill material 350 may comprise any suitable material, such as a liquid or a pre-applied epoxy compound.

Electrically conductive structure 340 electrically connects microelectronic device 100 and microelectronic device 300 to each other, while underfill material 350 protects electrically conductive structure 340 from internal stress, such as that due to CTE mismatches between various package components. An alternative (non-illustrated) embodiment makes use of surface activated bonding (SAB). In that embodiment electrically conductive structure 340 can be eliminated, as can the underfill material used to protect it. (The underfill material will likely remain in place around electrically conductive structure 140.) It should be noted that underfill material may not be necessary to protect electrically conductive structure 340 even where it is present because the internal stress between electrically conductive trace 151 (or, more generally, the DBM layer) and microelectronic device 300 is not as great as it is between substrate 305 and microelectronic device 100. In other words, the protection and CTE stress relief afforded by an underfill material, while likely necessary or at least desirable for electrically conductive structure 140, may not be needed for electrically conductive structure 340, and almost certainly will not be needed (between microelectronic devices 300 and 100) where electrically conductive structure 340 is eliminated in favor of SAB.

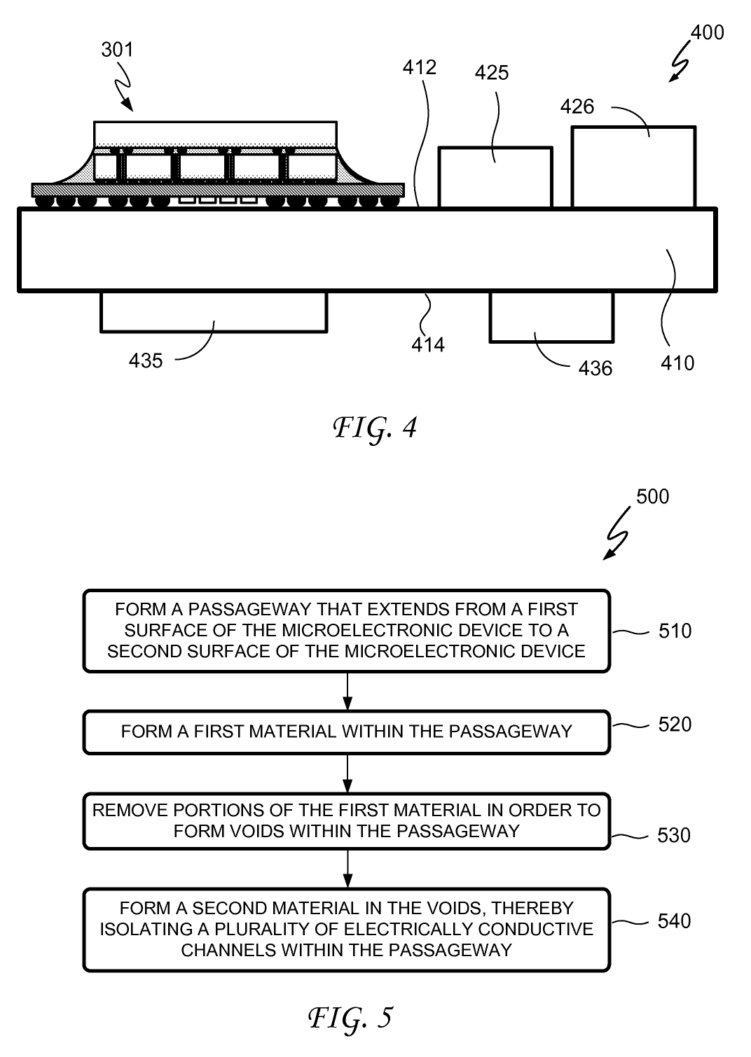

FIG. 4 is a schematic representation of a computing system 400 according to an embodiment of the invention. System 400 includes a number of components disposed on a board 410 (which can be any suitable type of mainboard, motherboard, or other circuit board or substrate). Board 410 includes a side 412 and an opposing side 414, and various components may be disposed on either one or both of sides 412 and 414. In the illustrated embodiment, computing system 400 includes stacked die package 301 disposed on side 412, and stacked die package 301 may comprise any of the embodiments described herein. As shown, the BGA balls or other electrically conductive structure 360 that are attached to the package substrate of stacked die package 301 electrically and mechanically attach stacked die package 301 and board 410 to each other.

System 400 may comprise any type of computing system, such as, for example, a hand-held or mobile computing device (e.g., a cell phone, a smart phone, a mobile internet device, a music player, a tablet computer, a laptop computer, a netbook computer, a nettop computer, etc.). However, the disclosed embodiments are not limited to hand-held and other mobile computing devices and these embodiments may find application in other types of computing systems, such as desk-top computers and servers.

As stated above, board 410 may comprise any suitable type of circuit board or other substrate capable of providing electrical communication between one or more of the various components disposed on the board. In one embodiment, for example, board 410 comprises a printed circuit board (PCB) comprising multiple metal layers separated from one another by a layer of dielectric material and interconnected by electrically conductive vias. Any one or more of the metal layers may be formed in a desired circuit pattern to route—perhaps in conjunction with other metal layers—electrical signals between the components coupled with board 410. However, it should be understood that the disclosed embodiments are not limited to the above-described PCB and, further, that board 410 may comprise any other suitable substrate.

In addition to the stacked die package, one or more additional components may be disposed on either one or both sides 412 and 414 of board 410. By way of example, and as shown in the figures, components 425 and 426 may be disposed on side 412 of board 410, and components 435 and 436 may be disposed on the board's opposing side 414. These components may be, for example, other IC devices (e.g., processing devices, memory devices, signal processing devices, wireless communication devices, graphics controllers and/or drivers, audio processors and/or controllers, etc.), power delivery components (e.g., a voltage regulator and/or other power management devices, a power supply such as a battery, and/or passive devices such as a capacitor), and one or more user interface devices (e.g., an audio input device, an audio output device, a keypad or other data entry device such as a touch screen display, and/or a graphics display, etc.), as well as any combination of these and/or other devices. In one embodiment, computing system 400 includes a radiation shield. In a further embodiment, computing system 400 includes a cooling solution. In yet another embodiment, computing system 400 includes an antenna. In yet a further embodiment, system 400 may be disposed within a housing or case. Where board 410 is disposed within a housing, some of the components of computer system 400—e.g., a user interface device (such as a display or keypad) and/or a power supply (such as a battery)—may be electrically coupled with board 410 (and/or a component disposed on the board) but be mechanically coupled with the housing.

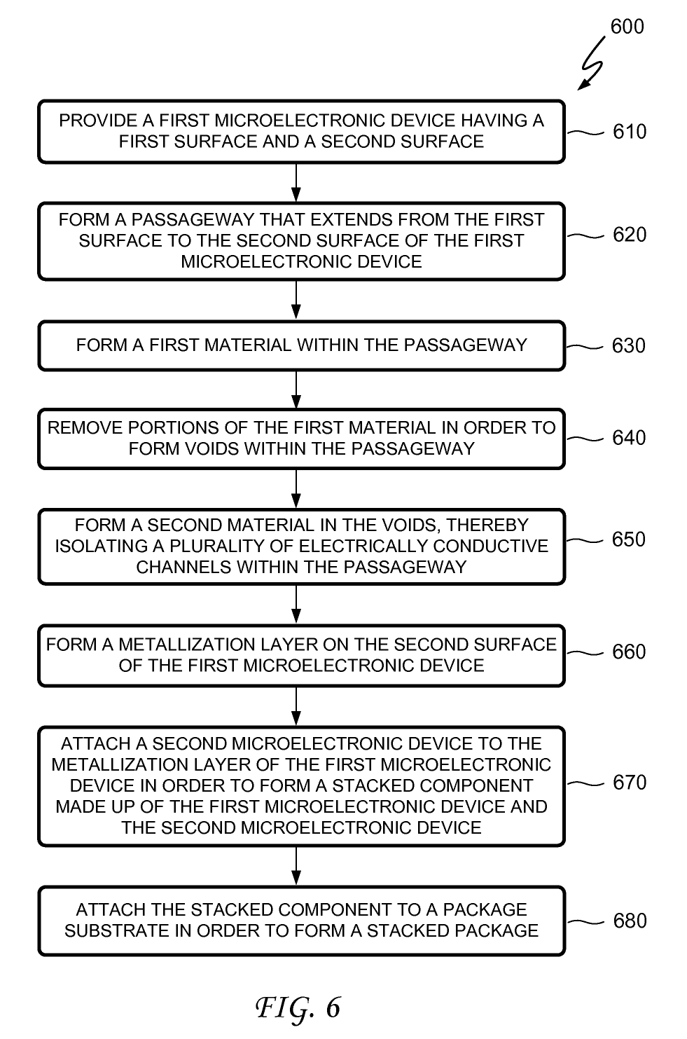

FIG. 5 is a flowchart illustrating a method 500 of manufacturing a multi-channel electrical communication pathway in a microelectronic device according to an embodiment of the invention. As an example, method 500 may result in the formation of a microelectronic device that is similar to microelectronic device 100 that is first shown in FIG. 1. FIG. 6 is a flowchart illustrating a method 600 of enabling electrical communication between components of a stacked-die package according to an embodiment of the invention. As an example, the stacked die package can be similar to stacked die package 301 (with its communication-enabling multi-channel TSVs) that is first shown in FIG. 3. Exemplary results of various steps of method 500 and method 600 are further illustrated in FIGS. 7-9 and FIG. 11, each of which include cross-sectional (a) and plan (b) views of microelectronic device 100 at various stages in its manufacturing process according to embodiments of the invention, as described below. As an example, a starting point for both method 500 and method 600 may be a silicon wafer.

With reference first to FIG. 5, a step 510 of method 500 is to form a passageway that extends from a first surface of the microelectronic device to a second surface of the microelectronic device. As an example, the passageway can be similar to passageway 130 that is first shown in FIG. 1 and that extends between surface 110 (e.g., similar to the “first surface”) and surface 120 (e.g., similar to the “second surface”) of microelectronic device 100. As another example, the passageway can be similar to a passageway 730 that has been formed (e.g., by using laser drilling or mechanical drilling processes) in a silicon (or other) substrate 700 (with a surface 710 and an opposing surface 720), as illustrated in FIG. 7.

A step 520 of method 500 is to form a first material within the passageway. As an example, the first material can be similar to one or the other of electrically insulating material 133 and the electrically conductive material used for electrically conductive channels 131, 132, 231, and/or 232. (In other words, either the electrically insulating or the electrically conductive material can be formed first.) It is noted that the word “form” as used in the foregoing description of step 520 (as well as in the description of any of the other steps of method 500 or of other methods according to embodiments of the invention) is intended in a very general sense that includes any means of causing the first material to end up in the passageway. For example, the meaning of “form” in this context is intended to encompass “plate” (as in an electroplating or other plating process), “grow,” “create,” “place,” “put,” etc.

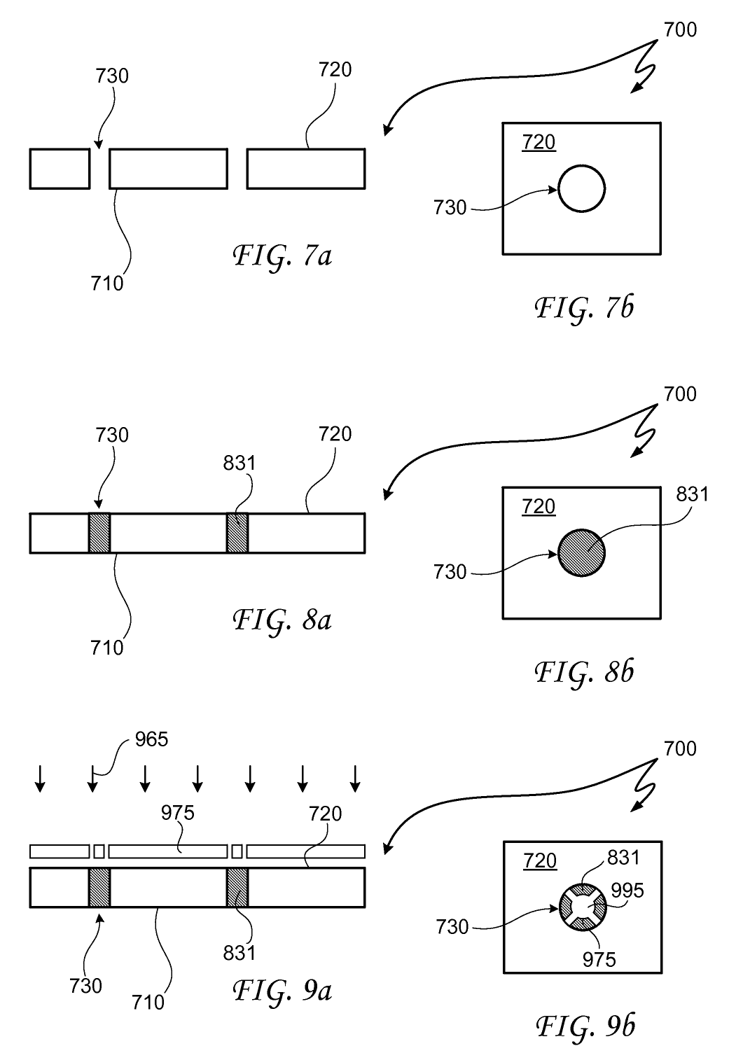

As an example, where the first material is an electrically conductive material, step 520 may involve an electroless plating process that forms a thin seeding layer (of copper, for example) in the passageway, followed by an electrolytic plating process that fills (or at least partially fills) the passageway with copper or another electrically conductive material. This is illustrated in FIG. 8, where an electrically conductive material 831 is shown within passageway 730. In FIG. 8 material 831 completely fills passageway 730; in a non-illustrated embodiment material 831 occupies a ring around the circular walls of the passageway while a cylindrical column at the center is empty. Other configurations are also possible.

A step 530 of method 500 is to remove portions of the first material in order to form voids (also referred to herein as “non-conductive valleys,” or “NCVs”) within the passageway. In some embodiments, a single void or NCV (of any suitable shape) may be formed. As an example, this may be accomplished using a mechanical drilling operation. As another example, the void may be formed by using a glass (or other) mask in conjunction with a laser etch 965. This is illustrated in FIG. 9, which shows a mask 975 providing a pattern that shapes the etching laser beam so as to cause it to etch out voids in a desired pattern. Any suitable pattern may be used; the pattern illustrated in FIG. 9 results in a void 995 yielding a plurality of isolated conductive channels similar to what is shown in FIG. 2. FIG. 9b shows mask 975 as being transparent so that surface 720, passageway 730, and electrically conductive material 831 are visible; if the mask were opaque or merely translucent (instead of transparent) these items would be completely concealed or at least partially obscured underneath it. FIG. 10 is a plan view of a portion of mask 975; this figure is included because it may be difficult to determine the appearance of mask 975 from FIG. 9 alone. Other mask patterns are also possible. In some embodiments, the quantity, location, and depth of the voids are at least somewhat dictated by laser etch and mask precision/control capabilities.

A step 540 of method 500 is to form a second material in the voids, thereby isolating a plurality of electrically conductive channels within the passageway. Step 540 (or another step) can also include a wafer grinding process designed to achieve the desired surface flatness and die thickness. As an example, this can comprise a CMP (chemical mechanical polish) operation or the like.

If the first material is an electrically conductive material then the second material is an electrically insulating material. On the other hand, if the first material is an electrically insulting material then the second material is an electrically conductive material; as mentioned above, either material may be formed before the other. More specifically, if step 520 forms an electrically conductive material in the passageway then step 540 forms an electrically insulating material in voids formed (in step 530) within that electrically conductive material. If instead step 520 forms an electrically insulating material in the passageway then step 540 forms an electrically conductive material in voids formed (in step 530) within that electrically insulating material. Regardless of which material is formed first, upon completion of step 540 a plurality of electrically conductive channels are isolated within the passageway, as described.

Examples of techniques for forming the electrically conductive material have been given above. As for the electrically insulating material, possible formation techniques include a TSV plugging process, in which the passageway is filled with a non-conductive fluid or with composite materials using techniques such as a dispense process, a pressure or vacuum suction process, or others.

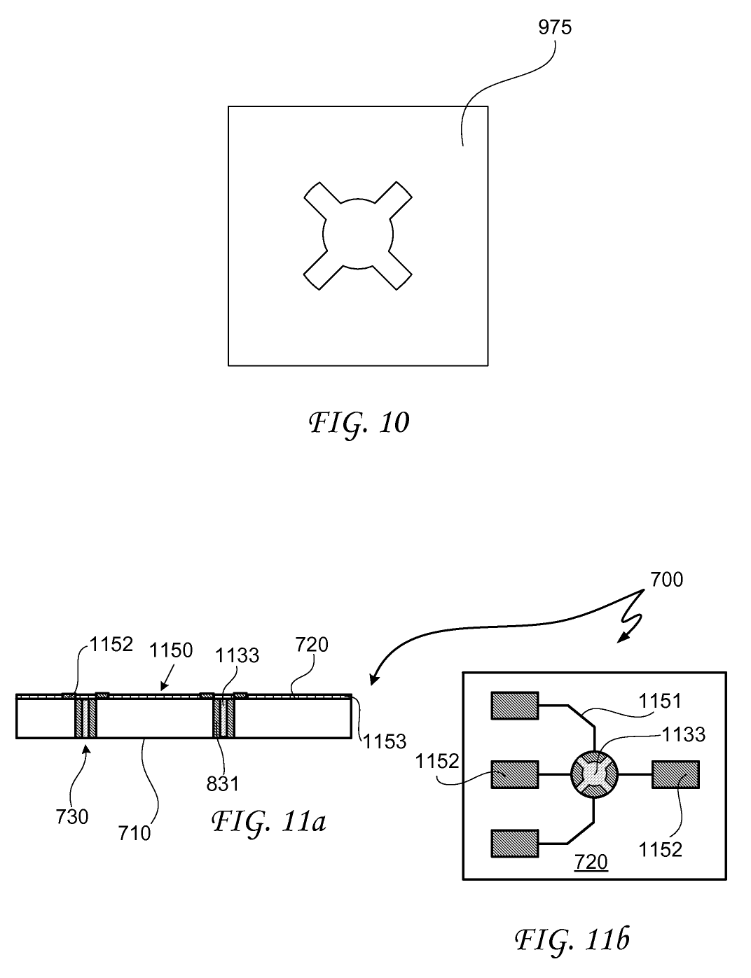

FIG. 11 depicts substrate 700 after step 540 has been performed. As illustrated, passageway 730 contains electrically conductive material 831 as well as electrically insulating material 1133 that has been formed in void 995 (visible in FIG. 9b). Also depicted in FIG. 11 is a DBM layer 1150 comprising DBM pads 1152, used for die-to-die interconnections, electrically conductive traces (DBM routing) 1151, and a passivation layer 1153. (The passivation layer is omitted from FIG. 11b.) DBM layer 1150 is formed using DBM processes that are well known in the art.

In one embodiment, forming the electrically conductive material (step 520 or step 540) comprises performing an electroless plating process in combination with an electrolytic plating process. In the same or another embodiment, removing portions of the first material (step 530) comprises using a laser etching process. In the same or another embodiment, the voids that are formed in step 530 are symmetric within the passageway.

Returning to FIG. 6, a step 610 of method 600 is to provide a first microelectronic device having a first surface and a second surface. As an example, the first microelectronic device can be similar to microelectronic device 100 that is first shown in FIG. 1.

A step 620 of method 600 is to form a passageway that extends from the first surface to the second surface of the first microelectronic device. As an example, the passageway can be similar to passageway 130 (first shown in FIG. 1) or passageway 730 (first shown in FIG. 7), and may be formed using one or more of the techniques described above.

A step 630 of method 600 is to form a first material within the passageway. As an example, the first material can be similar to one or the other of electrically insulating material 133 and the electrically conductive material used for electrically conductive channels 131, 132, 231, and/or 232, as described above in connection with method 500. As an example, the formation of the first material can be accomplished using methods and techniques described previously.

A step 640 of method 600 is to remove portions of the first material in order to form voids within the passageway. As an example, this may be accomplished using one or more of the techniques described above in connection with step 530 of method 500. Step 640 (or another step) can also include a wafer grinding process designed to achieve the desired surface flatness and die thickness. As an example, this can comprise a CMP operation or the like.

A step 650 of method 600 is to form a second material in the voids (wherein, as previously explained, one of the first material and the second material is an electrically conductive material and the other one of the first material and the second material is an electrically insulating material), thereby isolating a plurality of electrically conductive channels within the passageway. As an example, the formation of the second material can be accomplished using methods and techniques described previously.

A step 660 of method 600 is to form a metallization layer on the second surface of the first microelectronic device. As an example, the metallization layer can be similar to DBM layer 1150 that is shown in FIG. 11.

A step 670 of method 600 is to attach a second microelectronic device to the metallization layer of the first microelectronic device in order to form a stacked component made up of the first microelectronic device and the second microelectronic device. As an example, the second microelectronic device can be similar to microelectronic device 300 that is first shown in FIG. 3. The stacked component can be similar to the combination of microelectronic devices 100 and 300 as shown, for example, in FIG. 3. As an example, step 670 can comprise providing an electrically conductive structure (similar to electrically conductive structure 340 of FIG. 3, for example) at a surface of the second microelectronic device and attaching the electrically conductive structure to the metallization layer. If desired, an underfill material may also be provided. As another example, a surface activated bonding technique may be used. The details of how these structures and materials may be provided and put into place, and of how these processes and techniques may be carried out, are well known in the art and thus are not described in further detail herein.

A step 680 of method 600 is to attach the stacked component to a package substrate in order to form a stacked package. As an example, the package substrate can be similar to substrate 305 (first shown in FIG. 3). A structure resulting from the performance of step 680 (i.e., the stacked package) can, in one embodiment, be similar to stacked die package 301 (also first shown in FIG. 3). As mentioned previously, and in accordance with the foregoing description, the stacked package contains multi-channel TSVs that greatly enhance electrical communication between components of the package. The stacked package may be attached to a system board (such as board 410 of FIG. 4). Methods for attaching components to package substrates, and for attaching packages to system boards, are well known in the art and thus are not described in detail herein.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic device and the related structures and methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic device comprising:
a first surface;
a second surface; and
a passageway extending from the first surface to the second surface, the passageway containing a plurality of electrically conductive channels separated from each other by an electrically insulating material.

2. The microelectronic device of claim 1 wherein:
the first surface has an electrically conductive structure attached thereto.

3. The microelectronic device of claim 1 wherein:
the second surface has an electrically conductive trace formed thereon.

4. The microelectronic device of claim 1 wherein:
the microelectronic device comprises silicon; and
the passageway is a through-silicon via.

5. The microelectronic device of claim 1 wherein:
the passageway is cylindrical; and
the electrically insulating material comprises a center portion that is centrally located within the cylindrical passageway and further comprises a plurality of arms that radiate outward from the center portion.

6. A stacked die package comprising:
a substrate;
a first microelectronic device electrically connected to the substrate and comprising:
a first surface having an electrically conductive structure attached thereto;
an opposing second surface having a metallization layer formed thereon; and
a passageway extending from the first surface to the second surface, the passageway containing a plurality of electrically conductive channels separated from each other by an electrically insulating material; and
a second microelectronic device electrically connected to the metallization layer of the first microelectronic device.

7. The stacked die package of claim 6 further comprising:
a second electrically conductive structure attached to a surface of the second microelectronic device; and
an underfill material adjacent to the second electrically conductive structure.

8. The stacked die package of claim 6 wherein:
the passageway is cylindrical; and
the electrically insulating material comprises a center portion that is centrally located within the cylindrical passageway and further comprises a plurality of arms that radiate outward from the center portion.

9. A computing system comprising:
a board;
a user interface device disposed on the board; and
a stacked die package disposed on the board, the stacked die package comprising:
a substrate;
a first microelectronic device electrically connected to the substrate and comprising:
a first surface having an electrically conductive structure attached thereto;
an opposing second surface having a metallization layer formed thereon; and
a passageway extending from the first surface to the second surface, the passageway containing a plurality of electrically conductive channels separated from each other by an electrical insulating material; and
a second microelectronic device electrically connected to the metallization layer of the first microelectronic device.

10. The computing system of claim 9 further comprising:
a second electrically conductive structure attached to a surface of the second microelectronic device; and
an underfill material adjacent to the second electrically conductive structure.

11. The computing system of claim 10 further comprising:
a third electrically conductive structure attached to the substrate, wherein the third electrically conductive structure electrically and mechanically attaches the stacked die package and the board to each other.

12. The computing system of claim 9 wherein:
the passageway is cylindrical; and
the electrically insulating material comprises a center portion that is centrally located within the cylindrical passageway and further comprises a plurality of arms that radiate outward from the center portion.

13. A method of manufacturing a multi-channel electrical communication pathway in a microelectronic device, the method comprising:
forming a passageway that extends from a first surface of the microelectronic device to a second surface of the microelectronic device;
forming a first material within the passageway;
removing portions of the first material in order to form voids within the passageway; and
forming a second material in the voids, wherein one of the first material and the second material is an electrically conductive material and the other one of the first material and the second material is an electrically insulating material, thereby isolating a plurality of electrically conductive channels within the passageway.

14. The method of claim 13 wherein:
forming the electrically conductive material comprises performing an electroless plating process in combination with an electrolytic plating process.

15. The method of claim 13 wherein:
removing portions of the first material comprises using a laser etching process.

16. The method of claim 13 wherein:
removing portions of the first material comprises forming voids that are symmetric within the passageway.

17. A method of enabling electrical communication between components of a stacked-die package, the method comprising:
providing a first microelectronic device having a first surface and a second surface;
forming a passageway that extends from the first surface to the second surface of the first microelectronic device;
forming a first material within the passageway;
removing portions of the first material in order to form voids within the passageway;
forming a second material in the voids, wherein one of the first material and the second material is an electrically conductive material and the other one of the first material and the second material is an electrically insulating material, thereby isolating a plurality of electrically conductive channels within the passageway;
forming a metallization layer on the second surface of the first microelectronic device;
attaching a second microelectronic device to the metallization layer of the first microelectronic device in order to form a stacked component made up of the first microelectronic device and the second microelectronic device; and
attaching the stacked component to a package substrate in order to form a stacked package.

18. The method of claim 17 further comprising:
attaching the stacked package to a system board.

19. The method of claim 17 wherein:
attaching the second microelectronic device to the metallization layer of the first microelectronic device comprises:
providing an electrically conductive structure at a surface of the second microelectronic device and attaching the electrically conductive structure to the metallization layer; and
providing an underfill material adjacent to the electrically conductive structure.

20. The method of claim 17 wherein:
attaching the second microelectronic device to the metallization layer of the first microelectronic device comprises using a surface activated bonding technique.
